(19) United States
(12) Patent Application Publication
(10) Pub. No.: US 2025/0173655 A1
(43) Pub. Date: May 29, 2025

(54) METHODS, SYSTEMS, COMPUTER PROGRAMS AND COMPUTER-READABLE MEDIA FOR AUTOMATICALLY DESIGNING A WORKFLOW TO PERFORM A SEMICONDUCTOR INSPECTION TASK

(71) Applicant: Carl Zeiss SMT GmbH, Oberkochen (DE)

(72) Inventor: Abhilash Srikantha, Neu-Ulm (DE)

(21) Appl. No.: 18/519,993

(22) Filed: Nov. 27, 2023

(51) Int. Cl. G06Q 10/0633; G06N 20/00

(52) U.S. Cl. CPC G06Q 10/0633; G06N 20/00

(57) ABSTRACT

A computer implemented method for automatically designing a workflow for semiconductor inspection comprises: receiving input data to be processed by the workflow; receiving a natural language text describing at least a desired output of the workflow; using the natural language text as input to a trained workflow proposal machine learning model that generates one or more workflow proposals, each comprising a sequence of action items to generate the desired output when applied to the input data; prompting a user to confirm a workflow proposal; and applying the confirmed workflow proposal to the input data to perform a semiconductor inspection task. Corresponding computer programs, computer-readable media and systems are provided.

### FIELD

The disclosure relates to methods, systems, computer programs and computer-readable media for automatically designing a workflow to perform a semiconductor inspection task. The technology can including using natural language text as input.

### BACKGROUND

In semiconductor inspection, complex software is often used for image acquisition (e.g., volumetric reconstructions from cross beam images), image improvement (e.g., removing scan distortions, noise) and/or image evaluation (e.g., defect detection, defect evaluation, structure measurements). The corresponding software usually provides one or more workflows that can be selected by the user to evaluate the acquired images.

### SUMMARY

Often, such workflows cannot be modified to accustom user preferences, and/or they cannot be adapted to other tasks that involve a different workflow. Some flexibility can be provided using complex interfaces. These, however, can involve expert knowledge of the user, user training, detailed documentation and a help-desk system. Furthermore, designing new workflows can be a relatively time-consuming process for the designer, who often wants to obtain a high level of generality to allow for different application scenarios and user preferences.

The disclosure seeks to provide software and systems for semiconductor inspection tasks that is re-usable and adaptable to other tasks. The disclosure also seeks to improve the customizability, sustainability and/or applicability of software and systems for semiconductor inspection tasks. The disclosure further seeks to shorten the design cycle and/or improve the efficiency of the design process of such software and systems. The disclosure also seeks to provide software and systems for semiconductor inspection tasks that are usable and adaptable by non-expert users.

Certain embodiments of the disclosure relate to methods (e.g., computer implemented methods), computer-readable media, computer programs and systems for automatically designing a workflow for semiconductor inspection.

Some embodiments of the disclosure involve a computer implemented method for automatically designing a workflow for semiconductor inspection. The method can comprise: receiving input data to be processed by the workflow; receiving a natural language text describing at least a desired output of the workflow; using the natural language text as input to a trained workflow proposal machine learning model that generates one or more workflow proposals each comprising a sequence of action items to generate the desired output when applied to the input data; prompting a user to confirm a workflow proposal; and applying the confirmed workflow proposal to the input data to perform a semiconductor inspection task.

In some embodiments, a semiconductor inspection task comprises many different applications, e.g., the inspection of photolithography masks and the inspection of wafers. A semiconductor inspection task can comprise defect detection, defect localization, defect segmentation, defect assessment, structure measurements, critical dimension measurements, repair shape generation, etc.

A semiconductor inspection task can be organized as a data-flow and can comprise components such as data input, data preprocessing, data analysis, output postprocessing. The data input stage refers to importing (multi-modal) data and relevant meta-data (e.g., pixel size, milling depth range, landing energy, dwell time, metrology blueprint etc.) The data pre-processing stage refers to transforming input data into a predefined format via e.g., image registration, image alignment, conducting data quality checks, fiducial alignment etc. The data analysis extracts information from underlying data e.g., defect detection, defect classification, segmentation, object detection, dimension measurement, instance tracking, 2D/3D morphological analysis etc. The output post-processing steps are e.g., generating plots using the results from data analysis, overlaying results on input images, exporting selected results onto a csv file etc.

The term “workflow” refers to a sequence of action items that is performed in order to carry out a task, e.g., a semiconductor inspection task. The term “action item” refers to a building block of a workflow that performs a subtask. Action items can, for example, comprise: “input data import”, “input data alignment”, “annotation”, “object detection”, “contour extraction”, “segmentation”, “depth estimation”, “tracking”, “structure measurements”, “plotting”, “distance transform”, “histogram”, “average value”, etc.

The input data to be processed by the workflow can comprise any kind of data the workflow shall be applied to, for example one or more imaging datasets, time series data, text, etc.

A natural language text comprises a number of written words in any language. Instead of natural language texts, other input methods are conceivable as well. For example, visual sketches of the workflow could be used as a description of the workflow.

Instead of selecting a workflow from a predefined limited set of workflows in a software, the user can indicate the input data to be processed by the workflow and describe the desired output of the workflow using a natural language text. The workflow proposal machine learning model is trained to automatically generate one or more workflow proposals from the natural language text. The workflow proposals transform the input data to the desired output data. In this way, various workflow proposals can be generated to solve various kinds of tasks according to user preferences. Thus, for example, the software can be flexible and widely applicable to various problems. Additionally or alternatively, the software can be re-usable, since it is not limited to a predefined set of workflows. This need not involve expert knowledge from users, extensive training, and/or detailed documentation of different interfaces or functionalities. In addition, the design cycle can be shortened.

According to an example, the method further provides options to the user to modify the confirmed workflow proposal. In this way, the applicability, sustainability and/or re-usability of the method can be further improved.

In an example, the method further comprises storing the input data and/or the confirmed workflow proposal in one or more databases. In this way, input data and/or confirmed workflow proposals can be used as training data for improving the workflow proposal machine learning model.

In an example, the workflow proposal machine learning model comprises a conditional random field. In this way, the generated workflow proposals can be improved.

In some embodiments, the method comprises collecting meta data values for meta data items describing properties of the input data and/or of workflow proposals and/or of the workflow to be designed. Based on meta data items similarities between different input data and/or workflow proposals and/or workflow proposals and the workflow to be designed can be found. These can, for example, be used to complete missing information in the natural language text, for consistency checks of workflow proposals, as additional input to the workflow proposal machine learning model, etc. In this way, the generated workflow proposals can be improved.

In an example, the meta data items are organized in a hierarchical way. The hierarchy level of the meta data items can, for example, express the level of specificity of the meta data items. Using hierarchically organized meta data items allows for an efficient collection of meta data items and meta data values.

According to an aspect, meta data values for meta data items are collected by prompting a user to indicate meta data values for meta data items for the input data and/or workflow proposals and/or the workflow to be designed. Alternatively or additionally, meta data values for meta data items are collected by applying a trained machine learning model for meta data extraction to the input data and/or workflow proposals and/or the natural language text. A user can be prompted to confirm the automatically generated meta data items and/or meta data values. By using machine learning models for meta data extraction, meta data values for meta data items can be collected quickly, automatically and without requiring additional user effort. By prompting a user, the collected meta data values for meta data items are more reliable, they can contain more exact descriptions and they can contain rare descriptions that have not been learned by the machine learning model for meta data extraction. The collected meta data values for meta data items can comprise meta data values that are collected for a predefined list of meta data items. Alternatively or additionally, the collected meta data values and the meta data items are both obtained by the user or by the machine learning model for meta data extraction.

In an example, one or more meta data items are associated with a similarity relevance value indicating the relevance of the meta data item for the similarity of different input data and/or different workflow proposals and/or workflow proposals and the workflow to be designed. For example, the purpose of a workflow proposal is more relevant to evaluate similarities than the time of generation of the workflow proposal. In this way, relevance weighted similarities can be used to find similarities with a higher accuracy.

In an example, meta data values for meta data items are associated with workflow proposals and with the workflow to be designed, and the workflow proposal machine learning model additionally uses further workflow proposals as input, the further workflow proposals being associated with meta data values that are similar to the meta data values associated with the workflow to be designed. The further workflow proposals can, for example, be used to derive additional information for the workflow to be designed that is not given in the natural language text. Thus, the workflow proposals can be improved.

According to an aspect, options are automatically provided to the user to complete the natural language text during entering the natural language text. In this way, the entering of the natural language text is simplified and can be accomplished more quickly. In addition, during text completion, the user can directly be hinted at important information that should be indicated in the natural language text. Thus, the workflow proposals can be improved.

According to some embodiments, a computer implemented method for training a workflow proposal machine learning model according to any one of the methods described above comprises: obtaining training data comprising workflows containing sequences of action items and natural language texts describing at least an output of the workflows; modifying parameters of the workflow proposal machine learning model, thereby minimizing an objective function.

According to some embodiments, the training data comprises similarities of action items. These can, for example, be derived from descriptions of action items. The similarities of action items can be used to speed up the training and to improve the workflow proposals.

In an example, rules are derived from the training data, and the validity of sequences of action items is evaluated using the derived rules. These rules can be used during training to improve the workflow proposals and speed up the training process. They can also be used for consistency checks to evaluate the generated workflow proposals, thus improving the results.

In an example, associations between evaluation metrics and action items are derived from the training data. In this way, consistency checks can be carried out and the generated workflow proposals can be improved. In addition, the associations can be used to improve and speed up the training process.

A computer program according to some embodiments comprises instructions which, when the program is executed by a computer, cause the computer to carry out a method according to any one of the preceding claims.

A computer-readable medium according to some embodiments, stores a computer program executable by a computing device, the computer program comprising code for executing a method according to any of the methods described above.

A system for automatically designing a workflow for semiconductor inspection according to some embodiments comprises: one or more processing devices; and one or more machine-readable hardware storage devices comprising instructions that are executable by one or more processing devices to apply a method for automatically designing a workflow for semiconductor inspection according to any of the methods described above.

The disclosure described by examples and embodiments is not limited to the embodiments and examples but can be implemented by those skilled in the art by various combinations or modifications thereof.

### BRIEF DESCRIPTION OF THE DRAWINGS

FIG. 1 illustrates a flowchart of a computer implemented method for automatically designing a workflow for semiconductor inspection according to an embodiment of the disclosure;

FIG. 2 illustrates the application of a computer implemented method for automatically designing a workflow for semiconductor inspection according to an embodiment of the disclosure;

FIG. 3 shows an example workflow proposal that is automatically generated by the workflow proposal machine learning model for a natural language text;

FIG. 4 illustrates an exemplary meta data generation workflow that can be used to obtain meta data items and meta data values;

FIG. 5 illustrates further information that can be used for training the workflow proposal machine learning model;

FIG. 6 illustrates an embodiment of the disclosure that uses further workflow proposals as additional input to the workflow proposal machine learning model; and

FIG. 7 illustrates a system for automatically designing a workflow for semiconductor inspection according to an embodiment of the disclosure.

### DETAILED DESCRIPTION

In the following, exemplary embodiments of the disclosure are described and schematically shown in the figures. Throughout the figures and the description, same reference numbers are used to describe same features or components. Dashed lines indicate optional features.

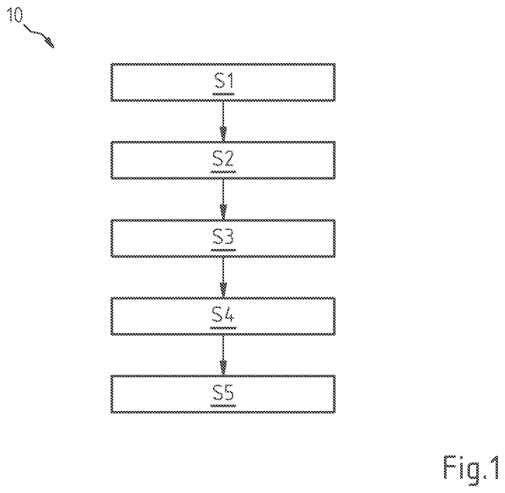

FIG. 1 illustrates a flowchart of a computer implemented method for automatically designing a workflow for semiconductor inspection according to some embodiments. The method comprises: receiving input data to be processed by the workflow in a step S1; receiving a natural language text describing at least a desired output of the workflow in a step S2; using the natural language text as input to a trained workflow proposal machine learning model that generates one or more workflow proposals each comprising a sequence of action items to generate the desired output when applied to the input data in a step S3; prompting a user to confirm a workflow proposal in a step S4; and applying the confirmed workflow proposal to the input data to perform a semiconductor inspection task in a step S5.

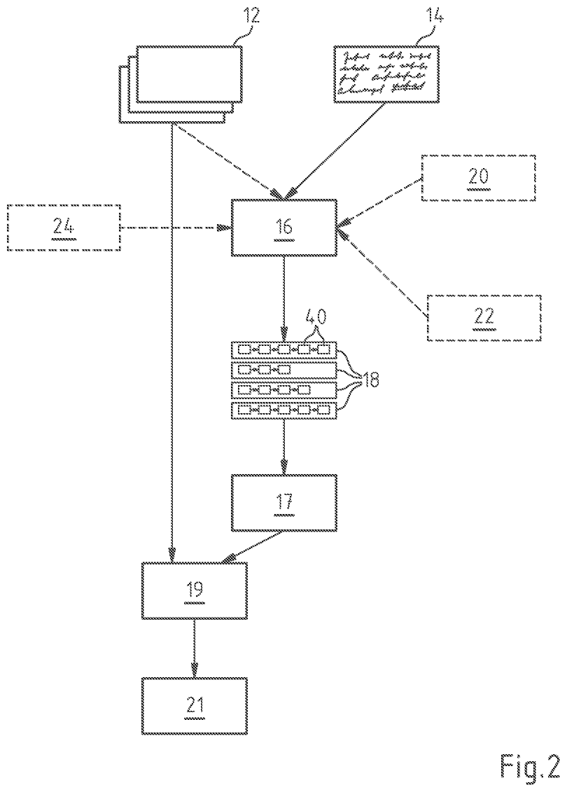

FIG. 2 illustrates an application of the computer implemented method for automatically designing a workflow for semiconductor inspection according to some embodiments. The workflow proposal machine learning model 16 receives the natural language text 14 as input and generates several workflow proposals 18. The workflow proposal machine learning model 16 can, optionally, receive the input data 12 as additional input. Each workflow comprises a set of action items 40 and generates the desired output 21 when applied to the input data 12. The number of action items 40 in the workflow proposals can differ. The workflow proposal machine learning model 16 can, optionally, use one or more databases 20, 22 containing additional information, e.g., meta information on the workflow proposals and/or the input data, further information 24 about action items, a collection of confirmed workflow proposals, documentation of workflows or action items, etc. The user is prompted to confirm a workflow proposal 18. The confirmed workflow proposal 17 is applied to the input data 12 to perform a semiconductor inspection task 19, thereby generating the desired output 21.

An imaging dataset can comprise one or more images of one or more portions of an object comprising integrated circuit patterns or of the whole object. An object comprising integrated circuit patterns can, for example, be a photolithography mask or a wafer. Various imaging modalities may be used to acquire an imaging dataset. Imaging datasets can comprise single-channel images or multi-channel images, e.g., focus stacks. For instance, it is possible that the imaging dataset includes 2-D images. It is possible to employ a multi beam scanning electron microscope (mSEM). mSEM employs multiple beams to acquire contemporaneously images in multiple fields of view. For instance, a number of not less than 50 beams could be used or even not less than 90 beams. Each beam covers a separate portion of a surface of the object comprising integrated circuit patterns. Thereby, a large imaging dataset is acquired within a short duration of time. Other examples for imaging datasets including 2D images relate to imaging modalities such as optical imaging, phase-contrast imaging, x-ray imaging, etc. It is also possible that the imaging dataset is a volumetric 3-D dataset, which can be processed slice-by-slice or as a three-dimensional volume. Here, a crossbeam imaging device including a focused-ion beam (FIB) source, an atomic force microscope (AFM) or a scanning electron microscope (SEM) could be used. Multimodal imaging datasets may be used, e.g., a combination of x-ray imaging and SEM. The imaging dataset can also comprise aerial images acquired by an aerial imaging system. An aerial image is the radiation intensity distribution at substrate level. It can be used to simulate the radiation intensity distribution generated by a photolithography mask during the photolithography process. The aerial image measurement system can, for example, be equipped with a staring array sensor or a line-scanning sensor or a time-delayed integration (TDI) sensor. The imaging dataset can also be a model dataset, e.g., a CAD dataset or a portion thereof or some other kind of model. The imaging dataset can also be a simulated dataset, e.g., an aerial image generated using a rigorous simulation method such as finite difference time domain (FDTD) or rigorous coupled wave analysis (RWCA), or a fast approximation method such as the thin element approximation (TEA).

The natural language text describing at least a desired output of the workflow can additionally contain specific action items that should appear in the workflow, descriptions of intermediate results of the workflow, user preferences, desired properties concerning the order of action items, e.g., that action item X follows action item Y, a description of the input data, a desired annotation type, measurements, etc. The natural language text can also comprise a complete description of the workflow or of parts thereof. Examples for natural language texts are “find defects in input data”, “segment defects from input data”, “compare input data to database data”, “measure average radius of tube structures”, “measure critical dimension of structures in input data”, “apply workflow X to five splits of Y dataset and report mean and variance of the L2-metric”, etc.

The natural language text can contain a description of the input data, e.g., additional information such as the acquisition method (SEM, xray, aerial image, etc.), the quality of the input data (high, low, etc.), properties of the input data (contrast, brightness, grey value or color range, data format, etc.), specific features of interest (regions of interest, defect types to be expected, type of semiconductor structures, structures of interest, etc.), etc.

The natural language text can contain descriptions of annotations to be carried out as a step in the workflow. For example, “annotate center points of all ellipsoidal structures with ellipticity at least 0.5, orientation between 5° and 70° and a pitch of 60 nm”, “annotate all circular structures with radius 80 nm arranged in a hexagonal grid with pitch 160 nm that have three inner concentric rings. Annotate each ring as a different class”.

In an example, the natural language text can be entered into a prompt by a user, and options are automatically provided to the user to complete the natural language text. Such options can be derived from a database containing previously entered natural language texts and/or previously confirmed workflow proposals including the natural language text, e.g., by using a machine learning model for text completion.

The input data can be used as additional input to the workflow proposal machine learning model. In this way, the generated workflow proposals can be directly adapted to the input data, e.g., to the format of the input data, to the grey value or color range of the input data, to the size of the input data, etc. Furthermore, information not included in the natural language text can be derived from the input data, e.g., the type of input data or the image acquisition method.

In an example, the user can give feedback to evaluate the generated workflow proposals of the workflow proposal machine learning model. The feedback can, for example, comprise a number on a scale indicating the quality of the workflow proposal. The feedback can, for example, indicate “good” or “bad”. Feedback information can also be automatically derived from the number of modifications the user applies to a workflow proposal before it is confirmed. The feedback can be used to improve and speed up the training of the workflow proposal machine learning model.

Instead of defining a workflow by a series of action items, which can involve expert knowledge, time, user effort and a highly flexible software, the method allows the user to describe the desired output of the workflow for a given input and automatically generates workflow proposals. The user can then confirm one of the proposals and apply the confirmed workflow proposal to the input data to perform a semiconductor inspection task.

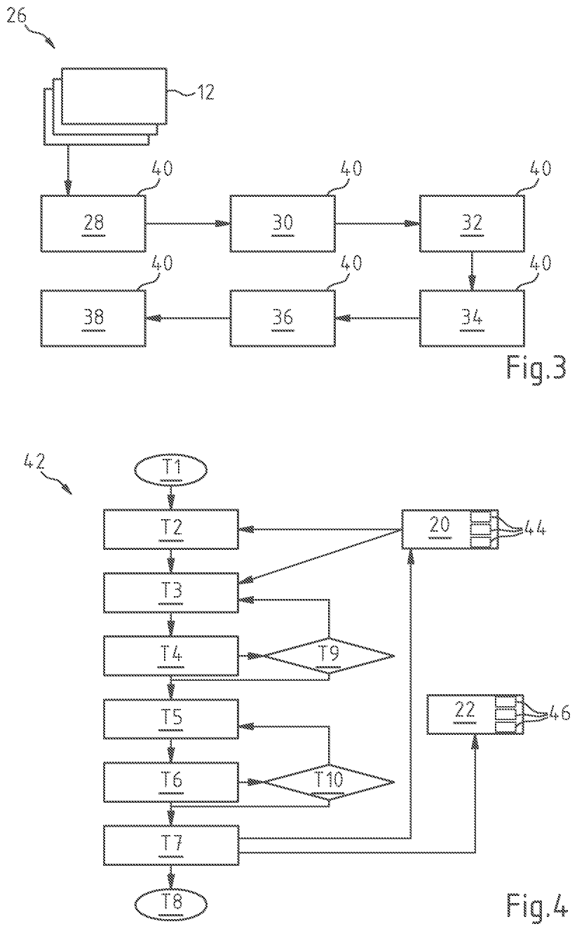

FIG. 3 shows an example workflow proposal 26 that is automatically generated by the workflow proposal machine learning model 16 for the natural language text “Plot distance statistics for distances between tubular structures”. The workflow proposal 26 comprises a sequence of action items 40 that sequentially process the input data 12. The sequence comprises the following action items 40: “import input data” 28, “align input data” 30, “object detection” 32, “contour extraction” 34, “distance computation” 36, “plotting” 38. By directly processing the natural language text given by the user, the workflow generation process is highly flexible, since it can be adapted to all kinds of tasks the user defines. In addition, it is much simpler and can be carried out faster by the user without requiring the help of a designer. Furthermore, it does not require expert knowledge on single action items or workflow design.

The workflow proposals are automatically generated by the trained workflow proposal machine learning model. The training data can, for example, consist of multiple natural language text descriptions of workflows for semiconductor inspection tasks describing at least a desired output of the workflow and the corresponding action-items as implemented by the workflows. The natural language text descriptions can sequentially describe the action-items and, therefore, contiguous portions of the descriptions may correspond to a single action-item. Alternatively, the natural language texts can only describe the desired output of the workflow, or they can describe sections of the workflow in a non-sequential order. The natural language text descriptions can be embedded by numerical representations, e.g., using one-hot- or Word2Vec like embeddings.

According to an embodiment, Hidden Markov Models (HMMs) can be used as workflow proposal machine learning models. They can be trained using natural language text descriptions as inputs and the action-item as hidden states. This model also allows for the inclusion of priors or a grammar on action-item sequences e.g., a preprocessing action-item is less likely to be included after a visualization action-item etc. The training of the HMM can, for example, be carried out using the Baum-Welch algorithm which is iteratively trained to maximize the probability of the correct N-action-item workflow for the corresponding natural language text description. During inference, Viterbi decoding is used to infer the best N-action-item workflow for the corresponding natural language text description using the pre-trained model. HMMs have limitations in input feature embeddings, and the workflow size is pre-determined. These limitations are addressed in further embodiments.

According to another embodiment, the workflow proposal machine learning model, for example, comprises a conditional random field. Conditional random fields (CRFs) are a class of statistical modeling methods often applied in pattern recognition and machine learning and used for structured prediction. Whereas a classifier predicts a label for a single sample without considering “neighboring” samples, a CRF can take context into account. To do so, the predictions are modelled as a graphical model, which represents the presence of dependencies between the predictions. What kind of graph is used depends on the application. For example, in natural language processing, “linear chain” CRFs are popular, for which each prediction is dependent only on its immediate neighbors.

In another embodiment, transformers can be used for processing the natural language text. Due to attention mechanisms of the transformers that enable modeling long-range dependencies between words of the natural language text, more complex natural language texts can be processed by the workflow proposal machine learning model, e.g., natural language texts with dependencies between different sections or natural language texts that do not sequentially describe the workflow.

According to some embodiments, the method can further provide options to the user to modify the confirmed workflow proposal. Modifications can be made in different ways, e.g., by natural language text descriptions, by explicitly adding, removing or replacing action items in the confirmed workflow proposal, by using a graphical user interface, by using a chat functionality, wherein the system provides modification options in response to user queries for modifications, etc. A graphical user interface could, for example, display the action items of the workflow proposal to the user in their correct order and offer the user a list of possible modifications when selecting one of the action items, e.g., using a mouse pointer. Possible modifications of an action item can, for example, comprise a list of action items the action item can be exchanged for, e.g., different annotation types. Possible modifications of a workflow proposal include the option to modify the order of action items, to delete and to add action items. The user can also indicate desired modifications via a natural language text. The natural language text could be automatically transformed into modifications to the workflow proposal by a trained machine learning model. The modified workflow proposal can be used as training data to improve the workflow proposal machine learning model.

According to some embodiments, the method further comprises storing the input data and/or the confirmed workflow proposal in one or more databases. In this way, a database of previously confirmed workflow proposals can be established. These previously confirmed workflow proposals can be used for training the workflow proposal machine learning model. They can also be used for selecting similar workflow proposals that carry out similar tasks and/or are applied to similar input data as the workflow to be designed. From these similar workflow proposals information can be obtained to complete the workflow to be designed, to have an initial guess for the workflow to be designed or to derive information not indicated in the natural language text, etc.

Such a previous workflow database can also be used for retrieving specific workflow proposals, e.g., workflow proposals generated within a specific timespan, workflow proposals applied to specific input data, workflow proposals for input data of a specific data acquisition method, workflow proposals for input data comprising specific structures or structure sizes, workflow proposals for input data exhibiting specific properties, etc. A query for workflow proposals can, for example, comprise “retrieve segmentation workflow proposals trained between 2020 and 2023 on wafer input data acquired using a SEM containing structure sizes between 80 and 120 nm and a pitch of 160 nm”, or “retrieve all workflow proposals that were applied to the X dataset”, or “retrieve all input data that was used for a specific semiconductor inspection task”, or “retrieve all input data including bounding box annotations” etc.

Previously confirmed workflow proposals can be loaded from the database for re-using them, e.g., as a pre-trained model that is adapted to a similar task via re-training on different training data, or as a trained model that is applied to different input data. In addition to the confirmed workflow proposals, the database can also store the input data, the natural language text, catch words from the natural language text, meta information for the confirmed workflow proposal, user feedback for the confirmed workflow proposal, annotations for an input dataset, usage statistics, timestamps, etc. This information can be stored in the same database or in a different database. This information can be used for training of the workflow proposal machine learning model, or during queries of the database, e.g., “retrieve all measurement workflow proposals for aerial images with a positive user feedback”. The workflow proposal machine learning model can be improved by retrieving all workflow proposals with negative user feedback and re-training the model.

According to some embodiments, the method comprises collecting meta data values for meta data items describing properties of the input data and/or of workflow proposals and/or of the workflow to be designed. Meta data items for describing properties of workflow proposals or the workflow to be designed comprise, for example, “structure type” (e.g., memory, logic, transistor, periphery), “vendor name” (e.g., companies that manufacture memory or logic chips), “imaging conditions” (e.g., low or high latency, low or high contrast, dwell time, pixel size, landing energy, milling rate), “purpose” (e.g., metrology, classification, detection, segmentation, regression, in particular anomaly or defect detection, fine or coarse metrology, 2D or 3D metrology), “result presentation” (e.g., statistic, plotting, metrics, analysis results, in particular coarse or fine structure statistics, intersection over union metrics, proximities, defect densities, false positive rates, defect source analysis) etc. Meta data items for describing properties of the input data comprise, for example, “quality”, “contrast variations”, “annotation type”, “annotation effort”, “size”, “acquisition method”, “acquisition time”, etc. Meta data items offer a way of describing a workflow proposal and/or input data and/or the workflow to be designed in a simple standardizes way, that is easy to store and query. It allows for indexing workflow proposals and/or input data to allow for a simple retrieval of specific workflow proposals and/or input data.

The meta data items can be organized in a hierarchical way. The hierarchy level of the meta data items can express the level of specificity of the meta data items. For example, a hierarchy could comprise the following meta data items: “annotations” on a first level, and “annotation type” and “annotation effort” on a second level. Annotation types comprise, for example, “bounding box”, “center point”, “contour”, “pixelwise”, while “annotation effort” can, for example, comprise “high”, “intermediate”, “low”. Another hierarchy could comprise the following meta data items: “Image quality” on a first level, and “latency”, “contrast”, “brightness”, “noise level” on a second level.

In an example, meta data values for meta data items are collected by prompting a user to indicate meta data values for meta data items for the input data and/or workflow proposals and/or the workflow to be designed. The user can be prompted for meta data items and corresponding meta data values. Alternatively, the meta data items can be predefined and the user is only prompted for corresponding meta data values. Alternatively, the user can be prompted to either indicate a meta data item and corresponding meta data value or to indicate a meta data value for one of the predefined meta data items. Predefined meta data items can be arranged in a list or a hierarchy of meta data items. The method can comprise the use of a mechanism configured for displaying meta data items (and, possibly, potential meta data values) to the user. Alternatively, the method can comprise the use of a mechanism configured for letting the user indicate meta data values for meta data items, e.g., using text or by selecting meta data values for meta data items on a screen.

Alternatively or additionally, meta data values for meta data items are collected by applying a trained machine learning model for meta data extraction to the input data and/or to workflow proposals and/or to the natural language text. The trained machine learning model for meta data extraction can generate meta data items and corresponding meta data values for a given input data and/or a workflow proposal and/or a natural language text. Alternatively, the trained machine learning model for meta data extraction can additionally use a list of meta data items as input and only generate meta data values for the list of meta data items from the input data and/or workflow proposals and/or natural language text.

In an example, meta data values for meta data items are generated automatically by a machine learning model for meta data extraction followed by prompting a user for confirmation according to a user preference. For example, meta data values for meta data items are first generated automatically by a machine learning model for meta data extraction. Then a user is prompted to confirm the generated meta data values for meta data items, to modify the meta data items and/or meta data values or to indicate further meta data items and/or meta data values.

In an example, meta data items are selected from a predefined list of meta data items. According to an aspect, the list of meta data items is extended by automatically adding a new meta data item to the list of meta data items in case an unknown meta data item is indicated multiple times for input data and/or workflow proposals and/or workflows to be designed, e.g., in answers given by one or more users when prompted for meta data values for meta data items. Thus, meta data items that repeatedly occur for describing input data, workflow proposals or the workflow to be designed can be automatically added to the list of meta data items. A user can be prompted for confirmation. Similarly, meta data items can be automatically removed from the list, e.g., if they have not been used for a specified timespan for describing input data, workflow proposals or the workflow to be designed. Meta data items can also be added, deleted or modified by a user. Meta data items can be arranged within a hierarchy by a user or automatically.

In some embodiments, the meta data values are used to find similarities between different input data and/or between different workflow proposals and/or between workflow proposals and the workflow to be designed. For example, for a given natural language text describing at least the desired output of the workflow to be designed, meta data values for meta data items can be derived, e.g., by prompting the user or by automatically deriving them using machine learning methods for meta data extraction. Similar previous workflow proposals can then be retrieved from a database using the similarity of meta data values for meta data items. For example, the k-nearest neighbors method can be used to find the k most similar workflow proposals based on meta data values for meta data items. The similarities can be weighted by a similarity relevance value indicating the relevance of a meta data item for the similarity as described below.

The similar workflow proposals can, for example, be used as additional input to the workflow proposal machine learning model. Such additional inputs can, for example, be used by the workflow proposal machine learning model to gain additional information about the desired workflow that is missing in the natural language text. Alternatively, the similarity of workflow proposals can be derived from the similarity of the input data. For example, workflow proposals for input data with similar meta data values as the meta data values for the given input data can be retrieved and used as additional input to the workflow proposal machine learning model. Meta data values for meta data items for input data can either be obtained by prompting a user, or by automatically deriving them from the input data. To this end, machine learning models can be used. Similar workflow proposals can also be used for consistency checks of the generated workflow proposals.

In an example, one or more meta data items are associated with a similarity relevance value indicating the relevance of the meta data item for the similarity of different input data and/or different workflow proposals and/or workflow proposals and the workflow to be designed. For example, meta data items such as “purpose of workflow”, “image acquisition method”, “workflow result” or “measurement metric” should be identical in similar workflow proposals and are, thus, assigned a higher similarity relevance value (weight) d than meta data items such as “training time”, “acquisition time” or “object size” that can differ in similar workflow proposals. By weighting different meta data items according to their similarity relevance value, workflow proposals and/or input data that are similar in the most important aspects can be retrieved.

FIG. 4 illustrates an exemplary meta data generation workflow 42 that can be used to obtain meta data items 44 and corresponding meta data values 46. After starting the meta data generation workflow in a step T1, a questionnaire is generated or selected from a meta data item database 20 containing meta data items 44 and questionnaires in a step T2. The questionnaire can comprise meta data items that are important for identifying the workflow proposal, e.g., the purpose of the workflow proposal, the type of input data, the results of the workflow proposal, the presence of annotations, etc. In a step T3, upon availability, a sub-questionnaire can be retrieved from the meta data item database 20 that contains more detailed questions on meta data items, e.g., the image acquisition type or the type of annotation. In a step T4 the user response is collected. In a step T9, the existence of a follow-up questionnaire is checked. In case a follow-up questionnaire exists, the process is repeated. Otherwise, in a step T5, sub-questions from meta data values are formulated. For example, the k-nearest neighbor method can be used to retrieve similar workflow proposals and input data. For example, if the purpose of the workflow to be designed differs from the k-nearest neighbor workflow proposals the user is questioned for a descriptive explanation. This dynamic way of formulating questions can provide insights into workflow generation and consistency and can be used to update the meta data item database 20. In a step T6, user responses are collected. In a step T10, the existence of follow-up questions is checked and in case a follow-up question exists the process is repeated. Finally, in a step T7 the meta data item database 20 and the meta data value database 22 are updated based on the user responses. Then the process ends in a step T8.

The meta data item database 20 contains various meta data items 44 describing categories applicable to workflow proposals and/or input data, e.g., in the form of graphs or trees or hierarchies containing meta data items 44 in the form of nodes.

The meta data item database 20 serves for collecting meta data items 44 and meta data values 46 from the user for any dataset. It is dynamic as nodes can be added/deleted/combined based on previous user responses. The hierarchy of the nodes can also be modified based on user responses. The meta data item database 20 aims at creating a homogenized description of each workflow proposal and input data such that similarities and differences between various workflow proposals and input data can be automatically analyzed.

The meta data value database 22 contains specific workflow proposals and input data together with corresponding meta data values 46 for meta data items 44 in the meta data item database 20. It can also contain text responses. Trends in the text responses can be automatically analyzed to update the meta data item database 20. E.g., if the user consistently comments for a meta data item “input data quality” the term “motion blur”, the term “motion blur” is automatically considered as a new meta data item 44 in the meta data item database 20. Techniques like topic modeling and unsupervised clustering can be used for clustering text responses and updating the meta data item database 20.

A computer implemented method for training a workflow proposal machine learning model according to any one of the embodiments described above comprises: obtaining training data comprising workflow proposals containing sequences of action items and natural language texts describing at least an output of the workflows; modifying parameters of the workflow proposal machine learning model, thereby minimizing an objective function.

For example, in case the workflow proposal machine learning model is an HMM, optimization can be carried out as described in the following.

A hidden Markov model describes the joint probability of a collection of “hidden” and observed discrete random variables. It relies on the assumption that the i-th hidden variable given the (i−1)-th hidden variable is independent of previous hidden variables, and the current observation variables depend only on the current hidden state. The Baum-Welch algorithm uses the well-known EM algorithm to find the maximum likelihood estimate of the parameters of a hidden Markov model given a set of observed feature vectors.

Let Xₜ be a discrete hidden random variable that can take on N possible values. Assuming that P(Xₜ|Xₜ₋₁) is independent of time leads to the definition of the time-independent stochastic transition matrix

$$A = ( {a}_{i j} ) = P ( {X}_{t} = j \vert {X}_{t - 1} = i ) .$$

The initial state distribution for t=1 is given by

$${π}_{i} = P ( {X}_{1} = i ) .$$

The observation variables Yₜ can take one of K possible values. Assuming that the observation given the “hidden” state is time independent, the probability of a certain observation yᵢ at time t for state Xₜ=j is given by

$${b}_{j} ( {y}_{i} ) = P ( {Y}_{t} = {y}_{i} \vert {X}_{t} = j ) .$$

Taking into account all the possible values of Yₜ and Xₜ, the N×K matrix

B=(bⱼ(yᵢ))

is obtained, where bⱼ belongs to all possible states and y; belongs to all possible observations.

An observation sequence is given by Y=(Y₁=y₁, Y₂=y₂, . . . , Y_{T}=y_{T}). Thus, a hidden Markov chain can be described as

θ=(A,B,π).

The Baum-Welch algorithm finds a local maximum for

$${θ}^{*} = arg {max}_{θ} P ( Y \vert θ ) .$$

Thus, the HMM parameters θ* maximize the probability of the observation.

In an example, the training data comprises further information 24, e.g., descriptions of action items, documentation of workflows or action items, rules about preceding or following action items or sequences of action items, about orders of action items, about a cooccurrence of action items in the same workflow, about a similarity of action items, about associations between action items and evaluation metrics, about exchangeable action items, etc. All kinds of further information can be included in the training data to improve or simplify the workflow proposal machine learning model. The action items and corresponding further information can be stored in a database.

The training data can, for example, comprise similarities of action items. These can, for example, be derived from descriptions of action items. For example, different annotation types are similar, whereas “segmentation” and “object detection” are dissimilar due to their differing purpose. Thus, action items with a high similarity can be easily exchanged in a workflow proposal, whereas dissimilar action items should not be exchanged in a workflow proposal.

The action items can be organized in a tree structure such that the selection of a higher level action item automatically involves a selection of an action item in the level below. For example, an action item “annotation” could be a higher level action item, and specific annotation type action items such as “bounding box annotation”, “center point annotation”, “pixelwise annotation”, “contour annotation” could be action items on the next lower level. Thus, the selection of an “annotation” action item is automatically followed by a selection of the annotation type action item. This structure can, for example, be imposed via pairwise probabilities in the optimization process, e.g., the actions-item pairs that should not appear in a sequence can have probability P(Xₜ|Xₜ₋₁)=0.

According to an example, rules are derived from the training data, and the validity of sequences of action items is evaluated using the derived rules. The training data comprises (mostly) valid workflow proposals. Thus, information about valid sequences of action items can be derived from the training data. For example, a “load images” action item precedes any further image processing item, whereas a “measure distance” action item can only follow an “object detection” or “segmentation” action item. To generate such rules, statistics can be used that indicate the probability of an action item following or preceding another action item.

According to an example, associations between evaluation metrics and action items are derived from the training data. For example, workflow proposals comprising a “segmentation” action item can be used for measuring critical distances using a CD metrology evaluation metric, whereas workflow proposals comprising a “defect detection” action item can be used for deriving defect statistics using a defect evaluation metric, e.g., number of defects, type of defects, defect density, etc.

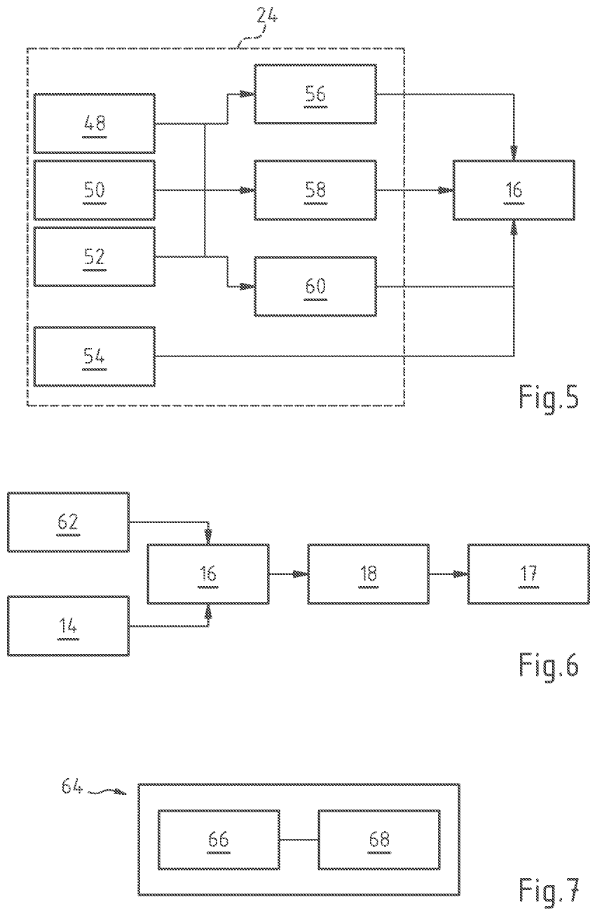

FIG. 5 illustrates further information 24 that can be used for training the workflow proposal machine learning model 16. The further information 24 comprises, for example, code functionalities 48, i.e., all functionalities the program provides for defining workflow proposals and action items, e.g., “load images”, “denoise images”, “align images”, “perform bounding box annotation”, “perform pixelwise annotation”, “perform bounding box annotation”, “train segmentation model”, “train object detection model”, “extract size”, “extract diameter”, “evaluate true positive rate”, “evaluate false positive rate”, “evaluate root-mean-squared-error”, “plot metric”, etc.). The further information 24 can also comprise documentations 50 provided by the code developers, e.g., textual descriptions of each functionality, module or action item. The further information 24 can also comprise previous workflow proposals 52. These can, for example, be used for consistency checks or for completing missing information or meta data values that are not given in the natural language text. The further information 24 can also comprise text descriptions 54 provided by the user, e.g., natural language text descriptions provided for previous workflow proposals or as answers to questions generated from the meta data item database or the meta data value database. From this further information, similarities 56 of different functionalities or action items can be derived. For example, a “pixelwise annotation” action item is similar to a “bounding box” annotation action item, whereas a “segmentation” action item and an “object detection” action item are dissimilar. Further, this information can be used to assess the validity of sequences of action items. In addition, rules 58 defining permissible orders of action items or functional grammars can be derived. Furthermore, evaluation metrics 60 can be associated with action items. For example, “segmentation” action items can be associated with “critical dimension metrology evaluation metrics”, whereas “defect detection” action items can be associated with “defect statistics evaluation metrics”. Some or all of this additional information 24 can be used as additional training data for training the workflow proposal machine learning model 16.

FIG. 6 illustrates an embodiment of the disclosure that uses further workflow proposals 62 as additional input to the workflow proposal machine learning model 16. The further workflow proposals 62 can, for example, be obtained using the k-nearest neighbor method for querying workflow proposals with similar meta data values. Here, similarity relevance values can be taken into account to weight meta data values according to their relevance for the workflow proposal similarity. Other methods can also be used to find similar workflow proposals, e.g., other clustering methods. The trained workflow proposal machine learning model 16 generates one or more workflow proposals 18, and the user confirms one of these proposals. The confirmed workflow proposal is subsequently applied to the input data.

A system 64 for automatically designing a workflow for semiconductor inspection according to an embodiment of the disclosure illustrated in FIG. 7 comprises: one or more processing devices 66; one or more machine-readable hardware storage devices 68 comprising instructions that are executable by one or more processing devices 66 to apply a method for automatically designing a workflow for semiconductor inspection according to any one of the embodiments, aspects or examples described above. The one or more processing devices 66 can, for example, be implemented as a CPU, GPU or TPU.

Reference throughout this specification to “an embodiment” or “an example” or “an aspect” means that a particular feature, structure or characteristic described in connection with the embodiment, example or aspect is included in at least one embodiment, example or aspect. Thus, appearances of the phrases “according to an embodiment”, “according to an example” or “according to an aspect” in various places throughout this specification are not necessarily all referring to the same embodiment, example or aspect, but may. Furthermore, the particular features or characteristics may be combined in any suitable manner, as would be apparent to one of ordinary skill in the art from this disclosure, in one or more embodiments.

Furthermore, while some embodiments, examples or aspects described herein include some but not other features included in other embodiments, examples or aspects combinations of features of different embodiments, examples or aspects are meant to be within the scope of the claims, and form different embodiments, as would be understood by those skilled in the art.

In summary, the disclosure relates to a computer implemented method for automatically designing a workflow for semiconductor inspection, the method comprising: receiving input data 12 to be processed by the workflow; receiving a natural language text 14 describing at least a desired output 21 of the workflow; using the natural language text 14 as input to a trained workflow proposal machine learning model 16 that generates one or more workflow proposals 18 each comprising a sequence of action items 40 to generate the desired output 21 when applied to the input data 12; prompting a user to confirm a workflow proposal 18; and applying the confirmed workflow proposal 17 to the input data 12 to perform a semiconductor inspection task 19. The disclosure also relates to corresponding computer programs, computer-readable media and systems.

In some embodiments, the various computations and/or processing of data described herein can be implemented by one or more computers according to the principles described above. In some examples, the processing of data can be performed by one or more cloud computer servers (also considered to be a computer as described herein). The one or more computers can include one or more data processors for processing data, one or more storage devices for storing data, such as one or more databases, and/or one or more computer programs including instructions that when executed by the one or more data processors cause the one or more data processors to carry out the processes. The computer can include one or more input devices, such as a keyboard, a mouse, a touchpad, and/or a voice command input module, and one or more output devices, such as a display, and/or an audio speaker. The computer can show graphical user interfaces on the display to assist the user.

In some embodiments, the computer can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described embodiments by operating on input data and generating output. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

The processes and logic flows described herein can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application-specific integrated circuit).

In some embodiments, the operations associated with processing of data described herein can be performed by one or more programmable processors executing one or more computer programs to perform the functions described in this document. A computer program can be written in any form of programming language, including compiled or interpreted languages, and it can be deployed in any form, including as a stand-alone program or as a module, component, subroutine, or other unit suitable for use in a computing environment.

For example, the computer can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer include one or more processors for executing instructions and one or more storage area devices for storing instructions and data. Generally, a computer will also include, or be operatively coupled to receive data from, or transfer data to, or both, one or more machine-readable storage media, such as hard drives, magnetic disks, magneto-optical disks, or optical disks. Machine-readable storage media suitable for embodying computer program instructions and data include various forms of nonvolatile storage area, including by way of example, semiconductor storage devices, e.g., EPROM, EEPROM, and flash storage devices; magnetic disks, e.g., internal hard disks or removable disks; magneto-optical disks; and CD-ROM and DVD-ROM discs.

In some embodiments, the processing of data described above can be implemented using software for execution on one or more mobile computing devices, one or more local computing devices, and/or one or more remote computing devices. For instance, the software forms procedures in one or more computer programs that execute on one or more programmed or programmable computer systems, either in the mobile computing devices, local computing devices, or remote computing systems (which may be of various architectures such as distributed, client/server, or grid), each including at least one processor, at least one data storage system (including volatile and non-volatile memory and/or storage elements), at least one wired or wireless input device or port, and at least one wired or wireless output device or port.

In some embodiments, the software may be provided on a medium, such as a CDROM, DVD-ROM, or Blu-ray disc, readable by a general or special purpose programmable computer or delivered (encoded in a propagated signal) over a network to the computer where it is executed. The functions may be performed on a special purpose computer, or using special-purpose hardware, such as coprocessors. The software may be implemented in a distributed manner in which different parts of the computation specified by the software are performed by different computers. Each such computer program can be stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The system may also be considered to be implemented as a computer-readable storage medium, configured with a computer program, where the storage medium so configured causes a computer system to operate in a specific and predefined manner to perform the functions described herein.

While this disclosure provides various embodiment details, these should not be construed as limitations on the scope of the disclosure or of what may be claimed, but rather as descriptions of features specific to particular embodiments of the disclosure. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations may be described in a particular order, this should not be understood as requiring that such operations be performed in the particular order described or in sequential order, or that all described operations be performed, to achieve desirable results. In certain circumstances, multitasking and parallel processing may be advantageous. Moreover, the separation of various system components in the embodiments described above should not be understood as requiring such separation in all embodiments.

Even though the disclosure has been described on the basis of specific embodiments, numerous variations and alternative embodiments will be apparent to a person skilled in the art, for example through combination and/or exchange of features of individual embodiments. Accordingly, it will be apparent to a person skilled in the art that such variations and alternative embodiments are also encompassed by the present disclosure, and the scope of the disclosure is restricted only within the scope of the appended patent claims and the equivalents thereof.

### REFERENCE NUMBER LIST

10 Computer implemented method
12 Input data
14 Natural language text
16 Workflow proposal machine learning model
17 Confirmed workflow proposal
18 Workflow proposals
19 Semiconductor inspection task
20 Meta data item database
21 Output
22 Meta data value database
24 Further information
26 Workflow proposal
28 Import data
30 Align data
32 Object detection
34 Contour extraction
36 Distance computation
38 Plotting
40 Action item
42 Meta data generation workflow
44 Meta data item
46 Meta data value
48 Code functionalities
50 Documentation
52 Workflow proposal
54 Text descriptions
56 Similarity
58 Rules
60 Evaluation metrics
62 Further workflow proposal
64 System
66 Processing device
68 Hardware storage device

What is claimed is:

1. A method, comprising:
using a computer to:
receive input data;
receive a natural language text describing a desired output;
use natural language text as input to a trained workflow proposal machine learning model that generates one or more workflow proposals, each workflow comprising a sequence of action items to generate the desired output when applied to the input data;
prompt a user to confirm a workflow proposal; and
apply the confirmed workflow proposal to the input data to perform a semiconductor inspection task.

2. The method of claim 1, further comprising using the computer to provide options to the user to modify the confirmed workflow proposal.

3. The method of claim 1, further comprising using the computer to store the input data and/or the confirmed workflow proposal in one or more databases.

4. The method of claim 1, wherein the workflow proposal machine learning model comprises a conditional random field.

5. The method of claim 1, further comprising using the computer to collect meta data values for meta data items describing properties selected from the group consisting of the input data, workflow proposals, and/or the workflow.

6. The method of claim 5, wherein the meta data items are organized in a hierarchical way.

7. The method of claim 5, further comprising using the computer to prompt a user to indicate the meta data values for the meta data items for the properties, thereby collecting the meta data values for the meta data items.

8. The method of claim 5, further comprising applying a trained machine learning model for meta data extraction to the input data, the workflow proposals, the natural language text, thereby collecting the meta data values for the meta data items.

9. The method of claim 5, wherein meta data items are selected from a predefined list of meta data items, and a new meta data item is automatically added to the list of meta data items when the meta data item is indicated multiple times for the input data and/or workflow proposals and/or the workflow.

10. The method of claim 5, further comprising using the meta data values to find similarities between different input data, different workflow proposals, and/or workflow proposals and the workflow.

11. The method of claim 5, wherein one or more meta data items are associated with a similarity relevance value indicating the relevance of the meta data item for the similarity of different input data, different workflow proposals, workflow proposals and the workflow.

12. The method of claim 5, wherein:
meta data values for meta data items are associated with workflow proposals and with the workflow to be designed;
the workflow proposal machine learning model uses further workflow proposals as input; and
the further workflow proposals are associated with meta data values that are similar to the meta data values associated with the workflow to be designed.

13. The method of claim 1, further comprising using the computer to store the input data and/or the confirmed workflow proposal in one or more databases.

14. The method of claim 1, further comprising, when entering the natural text, using the computer to automatically provide options to the user to complete the natural language text.

15. The method of claim 1, further comprising using a computer to:
obtain training data comprising workflows containing sequences of action items and natural language texts describing an output of the workflows; and
modify parameters of the workflow proposal machine learning model, thereby reducing an objective function to train the workflow proposal machine learning model.

16. The method of claim 14, wherein the training data comprises similarities of action items.

17. The method of claim 14, further comprising deriving rules from the training data, and using the derived rules to evaluate a validity of sequences of action items.

18. The method of claim 14, further comprising using the training data to derive associations between evaluation metrics and action items.

19. One or more machine-readable hardware storage devices comprising instructions that are executable by a computer to perform operations comprising:
receiving input data;
receiving a natural language text describing a desired output;
using natural language text as input to a trained workflow proposal machine learning model that generates one or more workflow proposals, each workflow comprising a sequence of action items to generate the desired output when applied to the input data;
prompting a user to confirm a workflow proposal; and
applying the confirmed workflow proposal to the input data to perform a semiconductor inspection.

20. A system, comprising:
one or more processing devices; and
one or more machine-readable hardware storage devices comprising instructions that are executable by one or more processing devices to perform operations comprising:
receiving input data;
receive a natural language text describing a desired output;
use natural language text as input to a trained workflow proposal machine learning model that generates one or more workflow proposals, each workflow comprising a sequence of action items to generate the desired output when applied to the input data;
prompt a user to confirm a workflow proposal; and
apply the confirmed workflow proposal to the input data to perform a semiconductor inspection.
